(19) United States
(12) Patent Application Publication
(10) Pub. No.: US 2025/0063892 A1
(43) Pub. Date: Feb. 20, 2025

(54) DISPLAY DEVICE

(71) Applicant: Samsung Display Co., LTD., Yongin-si (KR)

(72) Inventors: Tae Young SONG, Yongin-si (KR); Sun Young KWON, Yongin-si (KR); Bu Yong KIM, Yongin-si (KR); Jin Won KIM, Yongin-si (KR); Hye Jin PAEK, Yongin-si (KR); Won Gap YOON, Yongin-si (KR)

(21) Appl. No.: 18/435,828

(22) Filed: Feb. 7, 2024

(30) Foreign Application Priority Data
Aug. 17, 2023 (KR) 10-2023-0107488

(51) Int. Cl. H10K 59/122; H10K 50/19; H10K 59/127; H10K 59/38; H10K 59/80

(52) U.S. Cl. CPC H10K 59/122; H10K 50/19; H10K 59/127; H10K 59/38; H10K 59/873

(57) ABSTRACT

There is provided a display device including a first substrate including a light emission area and a non-light emission area; a first pixel electrode on the light emission area of the first substrate; a pixel defining layer on the non-light emission area of the first substrate, defining a first opening; a thin film encapsulation layer on the first pixel electrode and the pixel defining layer; a first light control layer overlapping the light emission area, on the thin film encapsulation layer; a planarization layer on the thin film encapsulation layer; and a bank pattern overlapping the non-light emission area, on the planarization layer and defining a second opening, wherein the first light control layer includes a first surface directed toward the first pixel electrode, a first side directed toward the bank pattern, and a first inclined surface connecting the first surface with the first side, and the planarization layer is in contact with the first inclined surface.

### CROSS-REFERENCE TO RELATED APPLICATION

The present application claims priority to and the benefit of Korean Patent Application No. 10-2023-0107488, filed on Aug. 17, 2023, in the Korean Intellectual Property Office, the entire content of which is incorporated by reference herein.

### BACKGROUND

### 1. Field

Embodiments of the present disclosure relate to a display device.

### 2. Description of the Related Art

With the advancement of multimedia, the importance of display devices has increased. Therefore, various types (or kinds) of display devices such as a liquid crystal display (LCD) device and an organic light emitting diode display (OLED) device have been developed.

Because a self-light emitting display device does not need a light source such as a backlight unit, the self-light emitting display device may be configured in a lightweight type (or kind) having low power consumption and to have high-quality characteristics such as a wide viewing angle, high luminance and contrast and a fast response speed, and thus has received attention as a next-generation display device.

### SUMMARY

Embodiments of the present disclosure provide a display device in which loss of light efficiency and deterioration of reliability are resolved or improved.

Embodiments of the present disclosure are not limited to those mentioned above and additional embodiments of the present disclosure, which are not mentioned herein, will be clearly understood by those skilled in the art from the following description of the present disclosure.

According to one or more embodiments of the disclosure, a display device includes a first substrate including a light emission area and a non-light emission area; a first pixel electrode on the light emission area of the first substrate; a pixel defining layer on the non-light emission area of the first substrate, and defining a first opening; a thin film encapsulation layer on the first pixel electrode and the pixel defining layer; a first light control layer overlapping the light emission area, on the thin film encapsulation layer; a planarization layer on the thin film encapsulation layer; and a bank pattern overlapping the non-light emission area, on the planarization layer and defining a second opening, wherein the first light control layer includes a first surface directed toward the first pixel electrode, a first side directed toward the bank pattern, and a first inclined surface connecting the first surface with the first side, and the planarization layer is in contact (e.g., direct physical contact) with the first inclined surface.

The first light control layer and the planarization layer may be on the thin film encapsulation layer in contact (e.g., direct physical contact) with the thin film encapsulation layer, and an inclined angle formed by the thin film encapsulation layer and the first inclined surface in a direction toward the non-light emission area is an acute angle.

The planarization layer may be between the thin film encapsulation layer and the first inclined surface by overlapping the light emission area.

The planarization layer may completely fill a space between the thin film encapsulation layer and the first inclined surface by overlapping the light emission area.

The first light control layer may include one selected from a quantum dot material and an organic material.

The planarization layer may include a metal scatterer (e.g., a metal light scatterer).

A display device may further comprise second light control layers spaced apart from each other with the planarization layer therebetween, wherein the second light control layer includes a second inclined surface that is in contact (e.g., direct physical contact) with the planarization layer.

The planarization layer further includes a first portion that is in contact (e.g., direct physical contact) with the first inclined surface, a second portion that overlaps the non-light emission area, and a third portion that may be in contact (e.g., direct physical contact) with the second inclined surface, and the second portion is between the first portion and the third portion.

The first portion and the third portion may be extended by the second portion, and the first portion, the second portion and the third portion are integrally formed.

The second portion may further include a first sub-portion extended from the first portion and a second sub-portion extended from the third portion, and the first sub-portion and the second sub-portion are spaced apart from each other with the bank pattern therebetween.

An inclined angle formed by the thin film encapsulation layer and the second inclined surface in a direction toward the non-light emission area may be an acute angle.

An inclined angle formed by the thin film encapsulation layer and the second inclined surface in a direction toward the non-light emission area may be either a right angle or an obtuse angle.

A display device may further comprise a first capping layer completely covering the first light control layer, the planarization layer and the second light control layer,
wherein the first capping layer is in contact (e.g., direct physical contact) with the first light control layer, the planarization layer and the second light control layer.

The planarization layer may completely be surrounded by the first light control layer, the first capping layer, the second light control layer and the thin film encapsulation layer.

The planarization layer may completely be surrounded by the first light control layer, the first capping layer and the thin film encapsulation layer.

The display device may further comprise a second substrate including a light-transmissive area and a light-shielding area; and a color filter layer on the light-transmissive area of the second substrate and provided toward the first substrate, wherein the second substrate faces the first substrate with a filler therebetween, and the color filter layer overlaps the first inclined surface of the first light control layer.

A width of the first opening in a parallel direction of the first substrate may be greater than a width of the second opening.

According to one or more embodiments of the disclosure, a display device includes a substrate including a first light emission area, a second light emission area and a non-light emission area between the first light emission area and the second light emission area; a pixel electrode on the first light emission area of the substrate; a pixel defining layer on the non-light emission area of the substrate; a first light control layer on the pixel electrode; a planarization layer on the pixel electrode and the pixel defining layer; and a bank pattern overlapping the non-light emission area, on the planarization layer, wherein the planarization layer includes a first portion that overlaps the first light emission area, and a second portion that overlaps the first light emission area, and on a plane, the first portion surrounds the first light control layer and the second portion surrounds the first light emission area.

A display device may further comprise a second light control layer that overlaps the second light emission area, wherein the planarization layer further includes a third portion that overlaps the second light emission area, the third portion is surrounds the second light control layer on a plane, and a width of the first portion is greater than that of the third portion on the plane.

The second portion may be surrounded by the bank pattern by overlapping the non-light emission area on a plane.

Further details of the other embodiments are included in the detailed description and drawings.

According to the embodiments of the present disclosure, a display device in which loss of light efficiency and deterioration of reliability are resolved or improved may be provided.

The effects according to the embodiments of the present disclosure are not limited to those mentioned above and more various effects are included in the following description of the present disclosure.

### BRIEF DESCRIPTION OF THE DRAWINGS

The above and other aspects and features of embodiments of the present disclosure will become more apparent by describing in more detail embodiments thereof with reference to the attached drawings, in which:

FIG. 1 is a schematic perspective view illustrating a display device according to one embodiment;

FIG. 2 is a schematic cross-sectional view illustrating a display device of FIG. 1;

FIG. 3 is a schematic plan view illustrating a display substrate of FIGS. 1-2;

FIG. 4 is a schematic plan view illustrating that a display driver and a driving circuit are attached to the display device of FIG. 3;

FIG. 5 is a schematic plan view illustrating a display substrate, which is enlarged from a portion ‘A’ of FIG. 4;

FIG. 6 is a schematic plan view illustrating a color conversion substrate corresponding to a portion ‘A’ of FIG. 5;

FIG. 7 is a cross-sectional view illustrating a display device according to one embodiment, which is taken along line X1-X1′ of FIG. 6;

FIG. 8 is an enlarged cross-sectional view illustrating a portion of a first light emission area of FIG. 7;

FIG. 9 is an enlarged cross-sectional view illustrating a portion ‘T1’ of FIG. 7;

FIG. 10 is a schematic plan view illustrating arrangement of a light control layer and a planarization layer of FIG. 7;

FIG. 11 is a cross-sectional view illustrating a display device according to another embodiment, which is taken along line X1-X1′ of FIG. 6;

FIG. 12 is an enlarged cross-sectional view illustrating a portion ‘T3’ of FIG. 11;

FIG. 13 is a schematic plan view illustrating arrangement of a light control layer and a planarization layer of FIG. 11;

FIG. 14 is a cross-sectional view illustrating a display device according to another embodiment, which is taken along line X1-X1′ of FIG. 6;

FIG. 15 is an enlarged cross-sectional view illustrating a portion ‘T5’ of FIG. 14; and

FIG. 16 is a schematic plan view illustrating arrangement of a light control layer and a planarization layer of FIG. 14.

### DETAILED DESCRIPTION

The subject matter of the present disclosure will now be described more fully herein with reference to the accompanying drawings, in which some embodiments of the present disclosure are shown. The subject matter of the present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

It is also to be understood that when a layer is referred to as being “on” another layer or substrate, it may be directly on the other layer or substrate, or one or more intervening layers may also be present. The same reference numbers indicate the same components throughout the specification.

It is to be understood that, although the terms “first,” “second,” etc. may be used herein to describe various elements, these elements should not be limited by these terms. These terms are used to distinguish one element from another element. For instance, a first element discussed below could be termed a second element without departing from the spirit and scope of the present disclosure. Similarly, the second element could also be termed a first element.

Unless otherwise defined, all terms (including technical and scientific terms) used herein have the same meaning as commonly understood by one of ordinary skill in the art to which the present disclosure pertains. It is also to be understood that terms defined in commonly used dictionaries should be interpreted as having meanings consistent with the meanings in the context of the related art, and are expressly defined herein unless they are interpreted in an ideal or overly formal sense.

Hereinafter, embodiments of the present disclosure will be described in more detail with reference to the accompanying drawings.

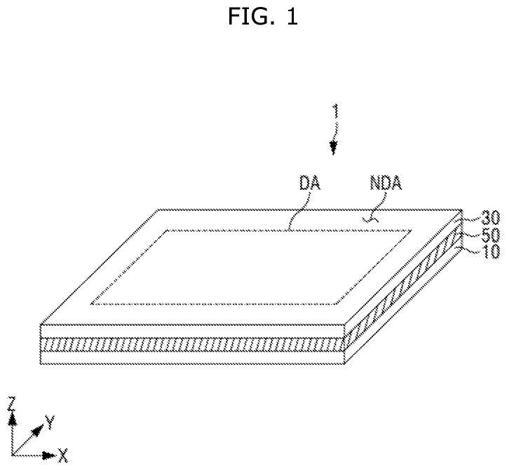

FIG. 1 is a schematic perspective view illustrating a display device according to one embodiment.

Referring to FIG. 1, a display device 1 may be applied to various suitable electronic devices such as small and medium-sized electronic devices, such as a tablet PC, a smart phone, a vehicle navigation unit, a camera, a center information display (CID) provided to a vehicle, a wristwatch-type electronic device, a personal digital assistant (PDA), a portable multimedia player (PMP) and/or a game machine, and/or medium and/or large-sized electronic devices such as television, an outdoor advertising board, a monitor, a desktop computer integrated with a monitor and/or a laptop computer. These examples are only suggested as non-limiting embodiments, and may be applied to other suitable electronic devices without departing from the concept of the present disclosure.

In some embodiments, the display device 1 may have a rectangular shape on a plane. For example, the display device 1 may include two first sides extended in a first direction (X-axis direction) and two second sides in a second direction (Y-axis direction) crossing the first direction (X-axis direction). A corner where the first side and the second side of the display device 1 meet may be formed at a right angle, but is not limited thereto, and may be rounded. In some embodiments, a length of the first side and a length of the second side may be different from each other, but is not limited thereto. The planar shape of the display device 1 is not limited to the illustrated example, and may be applied to a circular shape or other suitable shape.

The display device 1 may include a display area DA for displaying an image and a non-display area NDA for not displaying an image. Pixels respectively including a plurality of light emission areas may be in the display area DA to display an image. The non-display area NDA may be near the display area DA, and may surround the display area DA. An image displayed in the display area DA may be viewed by a user in a direction, toward which an arrow in the drawing is directed, in a third direction (Z-axis direction) crossing the first direction (X-axis direction) and the second direction (Y-axis direction).

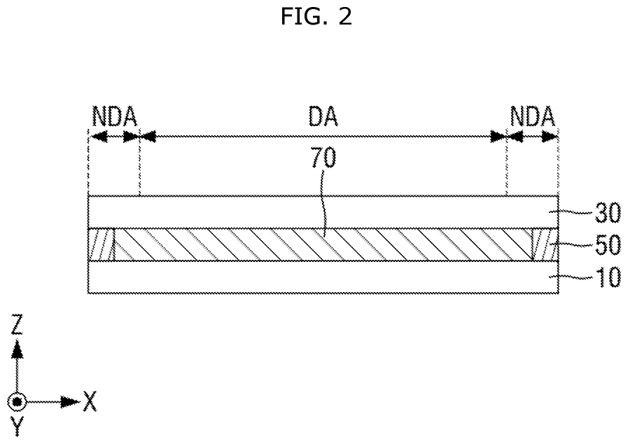

FIG. 2 is a schematic cross-sectional view illustrating the display device 1 of FIG. 1.

Referring to FIGS. 1-2, the display device 1 may further include a display substrate 10 and a color conversion substrate 30, and may further include a sealing portion 50 for coupling the display substrate 10 and the color conversion substrate 30 to each other and a filler 70 filled between the display substrate 10 and the color conversion substrate 30.

The display substrate 10 may include elements and circuits for displaying an image, for example, a pixel circuit such as a switching element, and a light control layer for converting a wavelength of light emitted from a self-light emitting element and a light emitting element or partially transmitting the light. In an embodiment, the self-light emitting element may include at least one selected from an organic light emitting diode, a quantum dot light emitting diode, an inorganic-based micro-light emitting diode (e.g., micro LED) or an inorganic-based nano-light emitting diode (e.g., nano LED). Hereinafter, a case that the self-light emitting element is an organic light emitting element will be described by way of example.

The color conversion substrate 30 may be on the display substrate 10, and may face the display substrate 10. The color conversion substrate 30 may include color filters.

The sealing portion 50 may be between the display substrate 10 and the color conversion substrate 30 by overlapping the non-display area NDA. The display substrate 10 and the color conversion substrate 30 may be coupled to each other by means of the sealing portion 50. For example, the sealing portion 50 may include or be formed of an organic material. For example, the sealing portion 50 may include or be made of an epoxy-based resin, but is not limited thereto.

The filler 70 may be in a space between the display substrate 10 and the color conversion substrate 30, which is surrounded by the sealing portion 50. The filler 70 may fill the space between the display substrate 10 and the color conversion substrate 30. The filler 70 may include or be made of a material capable of transmitting light. For example, the filler 70 may include or be made of an organic material. For example, the filler 70 may include a silicon-based organic material, an epoxy-based organic material or a mixture of a silicon-based organic material and an epoxy-based organic material.

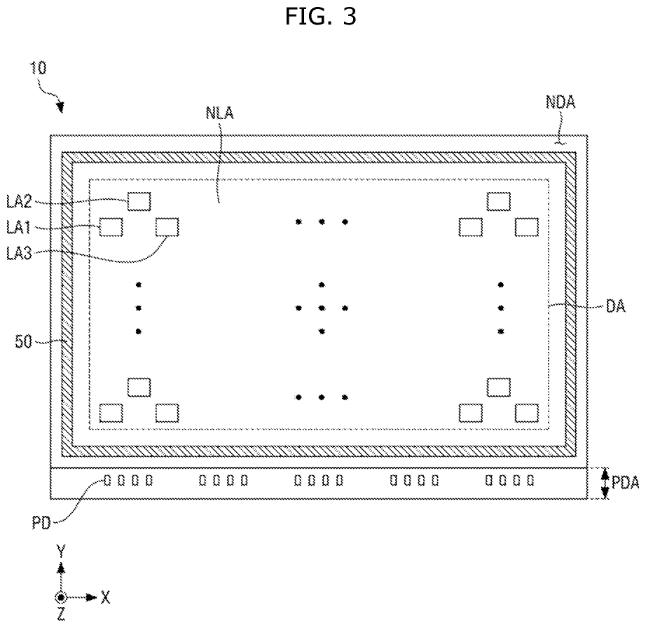

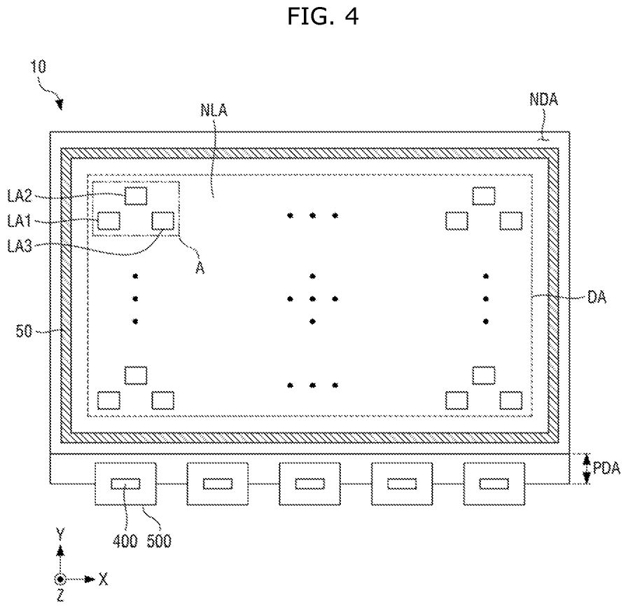

FIG. 3 is a schematic plan view illustrating the display substrate 10 of FIG. 1. FIG. 4 is a plan view illustrating that a display driver 400 and a circuit board 500 are attached to the display device of FIG. 3

Referring to FIG. 3, a plurality of light emission areas LA1, LA2 and LA3 and a non-light emission area NLA may be defined in the display area DA of the display substrate 10. The light emission areas LA1, LA2 and LA3 may include a first light emission area LA1, a second light emission area LA2 and a third light emission area LA3. The first light emission area LA1, the second light emission area LA2 and the third light emission area LA3 may be areas in which light generated by the display substrate 10 is emitted to the outside of the display substrate 10. The first light emission area LA1, the second light emission area LA2 and the third light emission area LA3 form one group, which may be defined as a plurality of groups in the display area DA.

The non-light emission area NLA may be an area in which light is not emitted to the outside of the display substrate 10. The non-light emission area NLA may surround each of the first light emission area LA1, the second light emission area LA2 and the third light emission area LA3 in the display area DA.

The sealing portion 50 may be in the non-display area NDA, and may be provided along the edge of the display substrate 10 to surround the display area DA.

The display substrate 10 may include a pad area PDA extended to one side of the non-display area NDA. A plurality of display pads PD may be in the pad area PDA. The display pad PD may be provided at a portion of the pad area PDA, which is adjacent to the long side, and the display pad PD may be electrically connected to a pixel circuit in the display area DA by means of a connection line and/or the like.

Referring to FIG. 4, the display driver 400 and the circuit board 500 may be attached to one side of the pad area PDA of the display substrate 10.

The circuit boards 500 may be on the display pad PD by overlapping the pad area PDA. The circuit boards 500 may be attached to the display pad PD by using a conductive adhesive member (e.g., an electrically conductive adhesive member) such as an anisotropic conductive film (e.g., an anisotropic electrically conductive film) and an anisotropic conductive adhesive (e.g., anisotropic electrically conductive adhesive). Therefore, the circuit boards 500 may be electrically connected to the display substrate 10 and signal lines. The circuit boards 500 may be flexible printed circuit boards and/or flexible films such as chip on films.

The display drivers 400 may be on the circuit board 500. Each of the display drivers 400 may be attached to the circuit board 500 in a chip on plastic (COP) scheme. In some embodiments, the display drivers 400 may be between the display pad PD and the display area DA by overlapping the pad area PDA. Each of the display drivers 400 may be attached to the pad area PDA of the display substrate 10 in a chip on glass (COG) scheme.

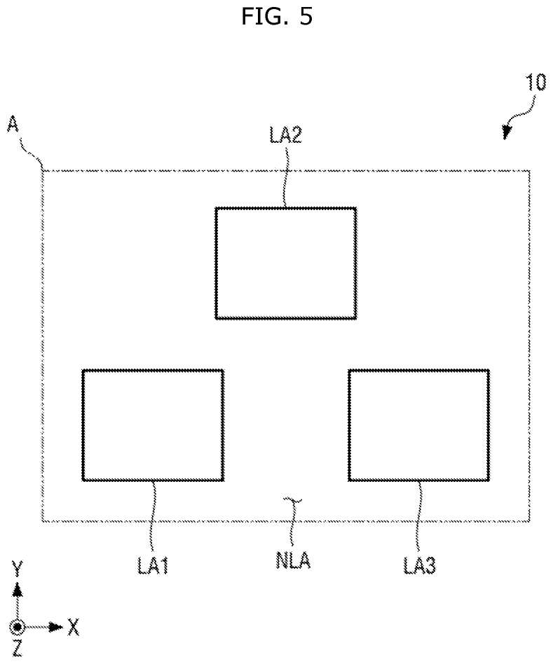

FIG. 5 is a plan view illustrating a portion ‘A’ of a display device in FIG. 4.

Referring to FIG. 5, the first light emission area LA1 and the third light emission area LA3, which are included in the display substrate 10, may be adjacent to each other in the first direction (X-axis direction), and the second light emission area LA2 may be provided at one side of the first light emission area LA1 and the third light emission area LA3 along the second direction (Y-axis direction), but the present disclosure is not limited thereto. The arrangement of the first light emission area LA1, the second light emission area LA2 and the third light emission area LA3 may be changed in various suitable ways.

In some embodiments, a planar shape of each of the first to third light emission areas LA1, LA2 and LA3 may be a quadrangle. For example, the quadrangle may be rectangular or square, but the present disclosure is not limited thereto. The planar shape of each of the first to third light emission areas LA1, LA2 and LA3 may have a circular shape, an oval shape, a diamond shape or other suitable polygonal shape.

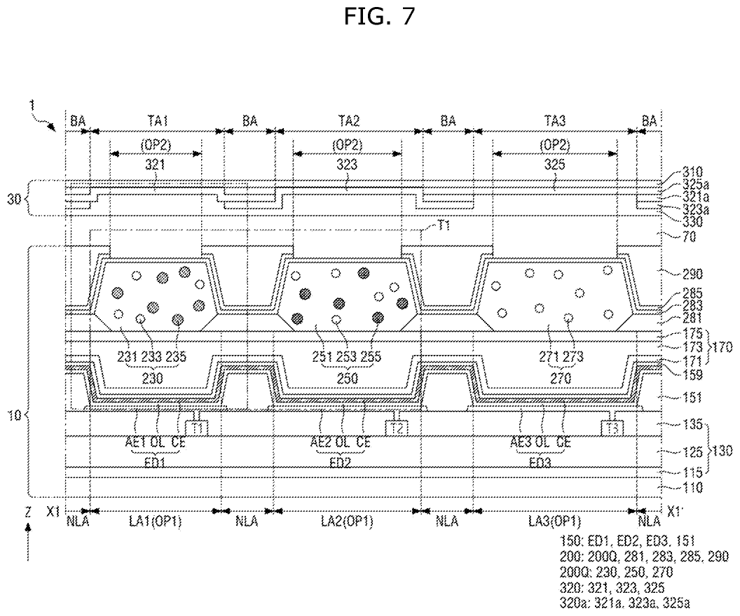

In some embodiments, each of the first light emission area LA1, the second light emission area LA2 and the third light emission area LA3 may emit light of a red color, a green color or a blue color, and colors of light emitted from each of the light emission areas LA1, LA2 and LA3 may be different from one another depending on types (or kinds) of light emitting elements (‘ED1’, ‘ED2’ and ‘ED3’ of FIG. 7), which will be further described herein below. In an embodiment, the first light emission area LA1 may emit first light of a red color, the second light emission area LA2 may emit second light of a green color, and the third light emission area LA3 may emit third light of a blue color, but the present disclosure is not limited thereto.

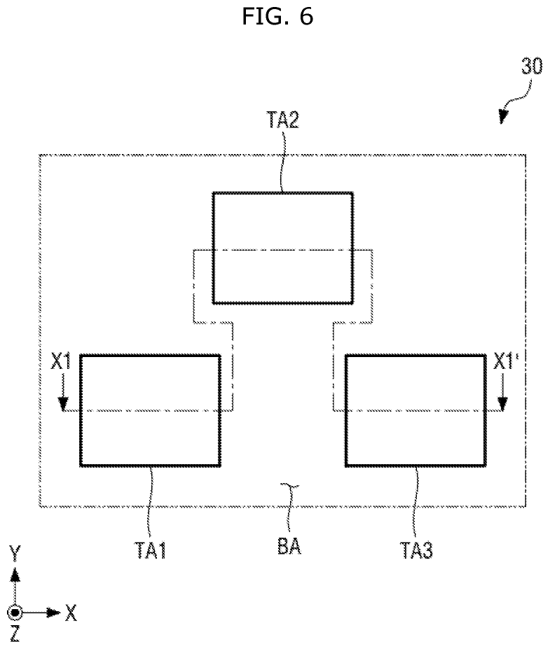

FIG. 6 is a schematic plan view illustrating a color conversion substrate 30 corresponding to a portion ‘A’ of FIG. 5.

Referring to FIG. 6, the color conversion substrate 30 may include light-transmissive areas TA1, TA2 and TA3 and a light-shielding area BA. The light-transmissive areas TA1, TA2 and TA3 of the color conversion substrate 30 may correspond to the light emission areas LA1, LA2 and LA3 of the display substrate 10. The light emitted from the light emission areas LA1, LA2 and LA3 of the display substrate 10 may be provided to the outside of the display device 1 by transmitting the light-transmissive areas TA1, TA2 and TA3 of the color conversion substrate 30.

The light-transmissive areas TA1, TA2 and TA3 may include a first light-transmissive area TA1, a second light-transmissive area TA2 and a third light-transmissive area TA3, which transmit light of their respective colors different from one another. Each of the plurality of light-transmissive areas TA1, TA2 and TA3 may emit red, green or blue light, and colors of light respectively transmitted from the light-transmissive areas TA1, TA2 and TA3 may be different depending on the corresponding emission areas LA1, LA2 and LA3. For example, the first light-transmissive area TA1 may correspond to or overlap the first light emission area LA1. In some embodiments, the second light-transmissive area TA2 may correspond to or overlap the second light emission area LA2, and the third light-transmissive area TA3 may correspond to or overlap the third light emission area LA3.

In some embodiments, when the display substrate 10 shown in FIG. 5 and the color conversion substrate 30 shown in FIG. 6 correspond to each other, the first light-transmissive area TA1 and the third light-transmissive area TA3 may be adjacent to each other along the first direction (X-axis direction), and the second light-transmissive area TA2 may be at one side of the first light-transmissive area TA1 and the third light-transmissive area TA3 along the second direction (Y-axis direction).

In some embodiments, a planar shape of the first light-transmissive area TA1, the second light-transmissive area TA2 and the third light-transmissive area TA3 may be a quadrangle. For example, the quadrangle may be rectangular or square, but the present disclosure is not limited thereto. The planar shape of each of the first light-transmissive area TA1, the second light-transmissive area TA2 and the third light-transmissive area TA3 may have a circular shape, an oval shape, a diamond shape or other suitable polygonal shape.

The light-shielding area BA may be an area in which light emitted from the display substrate 10 is not transmitted. The light-shielding area BA may surround the light-transmissive areas TA1, TA2 and TA3.

FIG. 7 is a cross-sectional view illustrating a display device 1 according to one embodiment, which is taken along line X1-X1′ of FIG. 6. The display substrate 10 and the color conversion substrate 30 may face each other with the filler 70 therebetween.

Referring to FIG. 7, the display substrate 10 may include a first substrate 110, a thin film transistor layer 130, a display element layer 150, a thin film encapsulation layer 170, a light controller 200, and a bank pattern 290. The first substrate 110 has been described as above and thus a duplicative description thereof will not be repeated here.

The thin film transistor layer 130 may be on the first substrate 110. The thin film transistor layer 130 may include a buffer layer 115, an insulating layer 125 (e.g., an electrically insulating layer 125), transistors T1, T2 and T3, and a via layer 135.

The buffer layer 115 may be on the first substrate 110. The buffer layer 115 may block or reduce permeation of particles and/or moisture through the first substrate 110. The buffer layer 115 may include an inorganic material. For example, the buffer layer 115 may include at least one of a silicon oxide (SiO₂), a silicon nitride (SiNx) or a silicon oxynitride (SiON). The buffer layer 115 may be formed of a single layer or a plurality of layers. In some embodiments, a plurality of signal lines (for example, gate lines, data lines, power lines, etc.) for transferring signals to the transistors T1, T2 and T3 may be further on the buffer layer 115.

The insulating layer 125 may be on the buffer layer 115 and the signal lines. The insulating layer 125 may protect the plurality of signal lines. The insulating layer 125 may include an inorganic material, and for example, may include silicon oxide (SiO₂), silicon nitride (SiNx) and/or silicon oxynitride (SiON). The insulating layer 125 may be formed of a single layer or a plurality of layers.

The transistors T1, T2 and T3 may be on the insulating layer 125. Each of the transistors T1, T2 and T3 included in the present embodiment may be a thin film transistor. The transistors T1, T2 and T3 may respectively overlap the light emission areas LA1, LA2 and LA3. For example, the first transistor T1 may overlap the first light emission area LA1, the second transistor T2 may overlap the second light emission area LA2, and the third transistor T3 may overlap the third light emission area LA3. Although it is shown in the drawings that the first transistor T1, the second transistor T2 and the third transistor T3 overlap the light emission areas LA1, LA2 and LA3 but do not overlap the non-light emission area NLA, this is only an example and the present disclosure is not limited thereto. In some embodiments, at least one of the first transistor T1, the second transistor T2 or the third transistor T3 may overlap the non-light emission area NLA. In some embodiments, all of the first transistor T1, the second transistor T2 and the third transistor T3 may overlap the non-light emission area NLA but may not overlap the light emission areas LA1, LA2 and LA3.

The via layer 135 may cover the transistors T1, T2 and T3. The via layer 135 may be a planarization layer for planarizing upper surfaces of the transistors T1, T2 and T3. In some embodiments, the via layer 135 may include an organic material. For example, the via layer 135 may include an acryl-based resin, an epoxy-based resin, an imide-based resin, an ester-based resin, and/or the like. In some embodiments, the via layer 135 may include a photosensitive organic material.

The display element layer 150 may be on the via layer 135. The display element layer 150 may include light emitting elements ED1, ED2 and ED3 and a pixel defining layer 151. The light emitting elements ED1, ED2 and ED3 may include pixel electrodes AE1, AE2 and AE3, a light emitting layer OL and a common electrode CE.

The pixel electrodes AE1, AE2 and AE3 may be on the via layer 135. The pixel electrodes AE1, AE2 and AE3 may be respectively in different light emission areas LA1, LA2 and LA3 to emit light of their respective colors different from one another. The pixel electrodes AE1, AE2 and AE3 may include a first pixel electrode AE1, a second pixel electrode AE2 and a third pixel electrode AE3, which respectively overlap the light emission areas LA1, LA2 and LA3. A portion of the pixel electrodes AE1, AE2 and AE3, which respectively overlap the light emission areas LA1, LA2 and LA3, may be extended to the non-light emission area NLA.

The pixel electrodes AE1, AE2 and AE3 may be electrically connected to the transistors T1, T2 and T3 by passing through the via layer 135. The pixel electrodes AE1, AE2 and AE3 may include a conductive metal (e.g., an electrically conductive metal). For example, the pixel electrodes AE1, AE2 and AE3 may have a stacked layer structure in which a material layer, which has a high work function, such as indium-tin-oxide (ITO), indium-zinc-oxide (IZO), zinc oxide (ZnO) and/or indium oxide (In₂O₃), and/or a reflective material layer such as Ag, Mg, Al, Pt, Pb, Pd, Au, Ni, Nd, Ir, Cr, Li, Ca and/or their mixture are stacked. In some embodiments, the pixel electrodes AE1, AE2 and AE3 may have a multi-layered structure of ITO/Mg, ITO/MgF, ITO/Ag, and ITO/Ag/ITO, but is not limited thereto.

The pixel defining layer 151 may be on the via layer 135 and the pixel electrodes AE1, AE2 and AE3. The pixel defining layer 151 may overlap the non-light emission area NLA. The pixel defining layer 151 may define a first opening OP1 for defining the light emission areas EA1, EA2 and EA3. In some embodiments, the light emission areas LA1, LA2 and LA3 and the non-light emission area NLA of the display substrate 10 may be defined by the pixel defining layer 151.

The pixel defining layer 151 may include an organic insulating material (e.g., an organic electrically insulating material) such as polyacrylates resin, epoxy resin, phenolic resin, polyamides resin, polyimides resin, unsaturated polyesters resin, poly phenylenethers resin, polyphenylenesulfides resin and/or benzocyclobutene (BCB).

The light emitting layer OL may be on the pixel electrodes AE1, AE2 and AE3. The light emitting layer OL included in the present embodiment may have a shape of a continuous film formed over the plurality of light emission areas LA1, LA2 and LA3 and the non-light emission area NLA.

The light emitting layer OL may include a tandem structure. In some embodiments, the light emitting layer OL of the display device 1 may include a structure in which a plurality of light emitting layers are stacked. That is, the light emitting layer OL according to an embodiment may include a structure in which a plurality light emitting organic layers are stacked. The tandem type light emitting layer OL may improve light efficiency and life characteristics of a display device. For example, the light emitting layer OL may include a first light emitting organic layer, a second light emitting organic layer, and a third light emitting organic layer, which are sequentially stacked, and the first light emitting organic layer, the second light emitting organic layer, and the third light emitting organic layer may be disposed to overlap each other. For example, the first light emitting organic layer may emit blue light, the second light emitting organic layer may emit green light, and the third light emitting organic layer may emit red light. Accordingly, the light emitting layer OL according to an embodiment may emit white light. However, the number of organic light emitting layers, the stacking order of organic light emitting layers, and the wavelength band of the organic light emitting layers are not limited thereto.

The light emitting layer OL of a tandem structure may improve light efficiency and lifespan characteristics of the display device

The common electrode CE may be on the light emitting layer OL. The common electrode CE may have a shape of a continuous film over the plurality of light emission areas LA1, LA2 and LA3 and the non-light emission area NLA. The common electrode CE may cover the light emitting layer OL over the plurality of light emission areas LA1, LA2 and LA3 and the non-light emission area NLA.

In some embodiments, the common electrode CE may have semi-transmissive properties or transmissive properties. When the common electrode CE has semi-transmissive properties, the common electrode CE may include Ag, Mg, Cu, Al, Pt, Pd, Au, Ni, Nd, Ir, Cr, Li, Ca, LiF/Ca, LiF/Al, Mo, Ti and/or their compound and/or mixture, for example, a mixture of Ag and Mg. When the common electrode CE has transmissive properties, the common electrode CE may include a transparent conductive oxide (TCO, e.g., a transparent electrically conductive oxide). For example, the common electrode CE may include a tungsten oxide (WxOy), a titanium oxide (TiO₂), an indium tin oxide (ITO), an indium zinc oxide (IZO), a zinc oxide (ZnO), an indium tin zinc oxide (ITZO), a magnesium oxide (MgO) and/or the like.

The element capping layer 159 may be on the common electrode CE. The element capping layer 159 may have a shape of a continuous film over the plurality of light emission areas LA1, LA2 and LA3 and the non-light emission area NLA. The element capping layer 159 may cover the common electrode CE over the plurality of light emission areas LA1, LA2 and LA3 and the non-light emission area NLA. The element capping layer 159 may prevent or reduce damage to the light emitting elements ED1, ED2 and ED3 from the external air, and may improve external light emitting efficiency.

The element capping layer 159 may include an inorganic insulating material (e.g., an inorganic electrically insulating material). For example, the element capping layer 159 may include at least one of an aluminum oxide (Al₂O₃), a titanium oxide (TiO₂), a tantalum oxide (Ta₂O₅), a hafnium oxide (HfO₂), a zinc oxide (ZnO), a silicon oxide (SiO₂), a silicon nitride (Si₃N₄) and/or a silicon oxycarbide (SiOC).

The thin film encapsulation layer 170 may be on the element capping layer 159. The thin film encapsulation layer 170 may have a shape of a continuous film over the plurality of light emission areas LA1, LA2 and LA3 and the non-light emission area NLA. The thin film encapsulation layer 170 includes at least one inorganic film to prevent or reduce permeation of oxygen and/or moisture into the display element layer 150. The thin film encapsulation layer 170 includes at least one organic film to protect the display element layer 150 from particles such as dust.

The thin film encapsulation layer 170 may include a first encapsulation layer 171, a second encapsulation layer 173 and a third encapsulation layer 175, which are sequentially stacked. The first encapsulation layer 171 and the third encapsulation layer 175 may be inorganic encapsulation layers, and the second encapsulation layer 173 between the first encapsulation layer 171 and the third encapsulation layer 175 may be an organic encapsulation layer.

Each of the first encapsulation layer 171 and the third encapsulation layer 175 may include one or more inorganic insulating materials (e.g., inorganic electrically insulating materials). The inorganic insulating material may include an aluminum oxide, a titanium oxide, a tantalum oxide, a hafnium oxide, a zinc oxide, a silicon oxide, a silicon nitride and/or a silicon oxynitride.

The second encapsulation layer 173 may include a polymer-based material. The polymer-based material may include an acryl-based resin, an epoxy-based resin, polyimide and/or polyethylene. For example, the second encapsulation layer 173 may include an acryl-based resin, for example, polymethyl methacrylate, polyacrylic acid and/or the like. The second encapsulation layer 173 may be formed by curing a monomer and/or coating a polymer.

In some embodiments, each of the first encapsulation layer 171 and the third encapsulation layer 175 may be formed of a single layer, but is not limited thereto. At least one of the first encapsulation layer 171 or the third encapsulation layer 175 may have a structure, in which a plurality of layers including or made of an inorganic material are stacked, for example, a multi-layered structure.

The light controller 200 may be on the thin film encapsulation layer 170. The light controller 200 may include a light control layer 2000, a planarization layer 281, a first capping layer 283, a second capping layer 285 and a bank pattern 290. The light control layer 2000 may include wavelength conversion layers 230 and 250 and a light-transmitting layer 270.

The wavelength conversion layers 230 and 250 and the light-transmitting layer 270, which are included in the light control layer 2000, may be on the third encapsulation layer 175. The wavelength conversion layers 230 and 250 may include a first wavelength conversion layer 230 and a second wavelength conversion layer 250. The first wavelength conversion layer 230, the second wavelength conversion layer 250 and the light-transmitting layer 270 may overlap each of the light emission areas LA1, LA2 and LA3. For example, the first wavelength conversion layer 230 may overlap the first light emission area LA1, the second wavelength conversion layer 250 may overlap the second light emission area LA2, and the light-transmitting layer 270 may overlap the third light emission area LA3.

In some embodiments, the first wavelength conversion layer 230 may include a first base resin 231 and a first scatterer 233 (e.g., a first light scatterer 233) dispersed in the first base resin 231, and may further include a first wavelength shifter 235 dispersed in the first base resin 231.

The first base resin 231 may include or be made of a material having high light transmittance. In some embodiments, the first base resin 231 may include or be made of an organic material. For example, the first base resin 231 may include an organic material such as an epoxy-based resin, an acryl-based resin, a cardo-based resin and/or an imide-based resin.

The first scatterer 233 may have a refractive index different from that of the first base resin 231, and may form an optical interface with the first base resin 231. For example, the first scatterer 233 may be a metal oxide particle and/or an organic particle. Examples of the metal oxide may include a titanium oxide (TiO₂), a zirconium oxide (ZrO₂), an aluminum oxide (Al₂O₃), an indium oxide (In₂O₃), a zinc oxide (ZnO) and/or a tin oxide (SnO₂), and examples of the organic particle material may include an acryl-based resin and/or a urethane-based resin.

An example of the first wavelength shifter 235 may include a quantum dot, a quantum rod, a phosphor and/or the like. For example, the quantum dot may be a granular material that emits light of a set or specific color while electrons are transited from a conduction band to a valence band. The quantum dot may have a set or specific band gap in accordance with its composition and size and thus may emit light having a unique wavelength after absorbing light. Examples of the semiconductor nano-crystal of the quantum dot may include group-IV nano-crystal, group II-VI compound nano-crystal, group Ill-V compound nano-crystal, group IV-VI nano-crystal or their combination.

The group II-VI compound may be selected from a group including or made of two-element compounds selected from a group of CdSe, CdTe, ZnS, ZnSe, ZnTe, ZnO, HgS, HgSe, HgTe, MgSe, MgS and their mixture; three-element compounds selected from a group of InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and their mixture; and four-element compounds selected from a group of HgZnTeS, CdZnSeS, CdZnSeTe, CdZnSTe, CdHgSeS, CdHgSeTe, CdHgSTe, HgZnSeS, HgZnSeTe, HgZnSTe and their mixture.

The group III-V compound may be selected from a group including or made of two-element compounds selected from a group of GaN, GaP, GaAs, GaSb, AlN, AlP, AlAs, AlSb, InN, InP, InAs, InSb and their mixture; three-element compounds selected from a group of GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP and their mixture; and four-element compounds selected from a group of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb and their mixture.

The group IV-VI compound may be selected from a group including or made of two-element compounds selected from a group of SnS, SnSe, SnTe, PbS, PbSe, PbTe and their mixture; three-element compounds selected from a group of SnSeS, SnSeTe, SnSTe, PbSeS, PbSeTe, PbSTe, SnPbS, SnPbSe, SnPbTe and their mixture; and four-element compounds selected from a group of SnPbSSe, SnPbSeTe, SnPbSTe and their mixture. The group IV element may be selected from a group of Si, Ge and their mixture. Group IV compound may be a two-element compound selected from a group of SiC, SiGe and their mixture.

At this time, the two-element compounds, the three-element compounds or the four-element compounds may exist in particles at a uniform (e.g., substantially uniform) concentration, or may exist in the same particle by being divided into states having partially different concentration distributions. Also, the two-element compounds, the three-element compounds or the four-element compounds may have a core/shell structure in which one quantum dot surrounds another quantum dot. An interface of the core and the shell may have a concentration gradient in which a concentration of an element existing in the shell is lowered along a direction toward the center of the core.

In some embodiments, the quantum dot may have a core-shell structure that includes a core having the aforementioned nano-crystal and a shell surrounding the core. The shell of the quantum dot may serve as a passivation layer for maintaining semiconductor characteristics by preventing or reducing occurrence of chemical denaturation of the core, and may also serve as a charging layer for giving electrophoresis characteristics to the quantum dot. The shell may be a single layer or a plurality of layers. Examples of the shell of the quantum dot may include an oxide of metal and/or non-metal, a semiconductor compound, or their combination.

For example, examples of the oxide of metal and/or non-metal may include a two-element compound such as SiO₂, Al₂O₃, TiO₂, ZnO, MnO, Mn₂O₃, Mn₃O₄, CuO, FeO, Fe₂O₃, Fe₃O₄, CoO, CO₃O₄, and/or NiO or a three-element compound such as MgAl₂O₄, CoFe₂O₄, NiFe₂O₄ and/or CoMn₂O₄, but the present disclosure is not limited thereto.

Also, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP and/or AlSb, but the present disclosure is not limited thereto.

The light emitted by the first wavelength shifter 235 may have a full width of half maximum (FWHM) of 45 nm or less, or 40 nm or less, or 30 nm or less, and color purity and color reproducibility of a color displayed by the display device 1 may be further improved. Also, the light emitted from the first wavelength shifter 235 may be emitted toward various suitable directions regardless of an incident direction of incident light. Therefore, lateral visibility of light displayed in the first light emission area LA1 may be improved.

In some embodiments, the second wavelength conversion layer 250 may include a second base resin 251 and a second scatterer 253 (e.g., a second light scatterer 253) dispersed in the second base resin 251, and may further include a second wavelength shifter 255 dispersed in the second base resin 251.

The second base resin 251 may include or be made of a material having high light transmittance. In some embodiments, the second base resin 251 may include or be made of an organic material. For example, the first base resin 231 may include an organic material such as an epoxy-based resin, an acryl-based resin, a cardo-based resin and/or an imide-based resin.

The second scatterer 253 has a refractive index different from that of the second base resin 251, and may form an optical interface with the second base resin 251. For example, the second scatterer 253 may be a light scattering particle. A detailed description of the second scatterer 253 is substantially the same as or similar to that of the first scatterer 233 and thus a duplicative description thereof will not be repeated here.

Examples of the second wavelength shifter 255 include a quantum dot, a quantum rod, and/or a phosphor. A more detailed description of the second wavelength shifter 255 is substantially the same as or similar to that of the first wavelength shifter 235 and thus a duplicative description thereof will not be repeated here.

In some embodiments, both the first wavelength shifter 235 and the second wavelength shifter 255 may include or be made of quantum dots. In this case, a particle size of the quantum dot constituting the second wavelength shifter 255 may be smaller than that of the quantum dot constituting the first wavelength shifter 235.

The light-transmitting layer 270 may include a third base resin 271 and a third scatterer 273 (e.g., a third light scatterer 273) in the third base resin 271. The light-transmitting layer 270 may not include a wavelength conversion material. The third scatterer 273 has a refractive index different from that of the third base resin 271, and may form an optical interface with the third base resin 271. For example, the third scatterer 273 may be a light scattering particle. A detailed description of the third scatterer 273 is substantially the same as or similar to that of the first scatterer 233 and thus a duplicative description thereof will not be repeated here.

The planarization layer 281 may be on the thin film encapsulation layer 170 by overlapping the non-light emission area NLA. The planarization layer 281 may be provided among the wavelength conversion layers 230 and 250 and the light-transmitting layer 270 and the thin film encapsulation layer 170 by overlapping the light emission areas LA1, LA2 and LA3.

The planarization layer 281 may include an organic material. The planarization layer 281 may include all organic materials that do not affect the lifespan of the wavelength conversion layers 230 and 250 and the light-transmitting layer 270. For example, the planarization layer 281 may include acrylate and the first to third base resins 231, 251 and 271, but is not limited thereto.

The first capping layer 283 may cover the wavelength conversion layers 230 and 250, the light-transmitting layer 270 and the planarization layer 281. The first capping layer 283 may be extended to overlap the light emission areas LA1, LA2, and LA3 and the non-light emission area NLA.

The first capping layer 283 may prevent or reduce damage to the wavelength conversion layers 230 and 250 and the light-transmitting layer 270 due to permeation of impurities such as external moisture and/or air.

The first capping layer 283 may include or be made of an inorganic material. For example, the first capping layer 283 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, and/or the like.

The second capping layer 285 may be on the first capping layer 283. The second capping layer 285 may be between the first capping layer 283 and the bank pattern 290 by overlapping the bank pattern 290 that will be further described herein below.

The second capping layer 285 may include a reflective function. The second capping layer 285 may prevent or reduce loss of light passing through the wavelength conversion layers 230 and 250 and the light-transmitting layer 270 that would otherwise occur by being absorbed into the bank pattern 290.

The second capping layer 285 may be a metal layer. For example, the second capping layer 285 may include at least one of Ag, Mg, Al, Pt, Pd, Au, Ni, Nd, Ir or Cr.

The bank pattern 290 may be on the second capping layer 285. The bank pattern 290 may overlap the non-light emission area NLA of the display substrate 10 and the light-shielding area BA of the color conversion substrate 30. The bank pattern 290 may define a second opening OP2 that overlaps the light emission areas LA1, LA2 and LA3. As shown in FIG. 7, the bank pattern 290 may have a reverse tapered shape in which a width of a lower surface directed toward the first substrate 110 is smaller than a width of an upper surface directed toward the second substrate 310. A width in a direction parallel with the first substrate 110 of the second opening OP2, which is defined by the bank pattern 290, may be smaller than a width of the first opening OP1 defined by the pixel defining layer 151. In some embodiments, the second opening OP2 may be in the first opening OP1.

The bank pattern 290 may perform a light absorbing function. The bank pattern 290 may prevent or reduce a color mixture defect of the display device 1, which may be caused by emission of light passing through the wavelength conversion layers 230 and 250 and the light-transmitting layer 270 to the non-light emission area NLA.

The bank pattern 290 may include a light absorbing material. For example, the bank pattern 290 may include an inorganic black pigment and/or an organic black pigment. The inorganic black pigment may be carbon black, and the organic black pigment may include at least one of lactam black, perylene black and/or aniline black, but the present disclosure is not limited thereto.

Referring to FIG. 7, the color conversion substrate 30 may include a second substrate 310, a plurality of color filter layers 321, 323 and 325, and a low refractive layer 330.

The second substrate 310 may be spaced apart from and face the first substrate 110. The second substrate 310 may include or be made of a light-transmitting material. The second substrate 310 may include a glass substrate or a plastic substrate. In some embodiments, the second substrate 310 may further include a separate layer on the glass substrate and/or the plastic substrate, for example, an insulating layer (e.g., an electrically insulating layer) such as an inorganic layer. The second substrate 310 may include a plurality of light-transmissive areas TA1, TA2 and TA3 and a light-shielding area BA.

The plurality of light-transmissive areas TA1, TA2 and TA3 may overlap the light emission areas LA1, LA2 and LA3 of the display substrate 10. For example, the first light-transmissive area TA1 may overlap the first light emission area LA1, the second light-transmissive area TA2 may overlap the second light emission area LA2, and the third light-transmissive area TA3 may overlap the third light emission area LA3. The light-shielding area BA of the color conversion substrate 30 may overlap the non-light emission area NLA of the display substrate 10.

The plurality of color filter layers 321, 323 and 325 may be on one surface of the second substrate 310. Each of the plurality of color filter layers 321, 323 and 325 may be provided toward the display substrate 10 on one surface of the second substrate 310. The color filter layers 321, 323 and 325 may include a first color filter layer 321, a second color filter layer 323 and a third color filter layer 325, which respectively overlap the light-transmissive area TA1, TA2 and TA3.

The plurality of color filter layers 321, 323 and 325 may include a colorant such as a dye and/or a pigment, which absorbs light of a wavelength band other than light of a set or specific wavelength band. The color filter layers 321, 323 and 325 may be respectively in the light-transmissive areas TA1, TA2 and TA3 to transmit only a portion of light incident from the corresponding light-transmissive areas TA1, TA2 and TA3 to the color filter layers 321, 323 and 325. Therefore, only the light transmitted by the color filter layers 321, 323 and 325 may be selectively emitted from the light-transmissive areas TA1, TA2 and TA3. In an embodiment, the first color filter layer 321 may be a red color filter layer, the second color filter layer 323 may be a green color filter layer, and the third color filter layer 325 may be a blue color filter layer. The light emitted from the plurality of light emitting elements ED1, ED2 and ED3 may be emitted to the outside of the display device 1 through the color filter layers 321, 323 and 325 by passing through the wavelength conversion layers 230 and 250 and the light-transmitting layer 270.

The color conversion substrate 30 may include color patterns 321a, 323a and 325a by overlapping the light shielding area BA. The color patterns 321a, 323a and 325a may be stacked in the order of the second color filter 323a, the first color filter 321a and the third color filter 325a in a direction toward the display substrate 10. The color patterns 321a, 323a and 325a may absorb external light by overlapping the light-shielding area BA, thereby reducing color distortion due to reflection of the external light. The color patterns 321a, 323a and 325a may have a structure in which the color filter layers 321, 323 and 325 including red, green and blue colors are stacked.

In some embodiments, the color patterns 321a, 323a and 325a may be replaced with a light-shielding member having a light-shielding function. For example, the light-shielding member includes or is made of a material used as a black matrix, and may absorb all (or substantially all) visible light wavelengths.

The low refractive layer 330 may be on the plurality of color filter layers 321, 323 and 325 and the color patterns 321a, 323a and 325a in a direction toward the display substrate 10. The low refractive layer 330 may prevent or reduce damage to or contamination of the color filter layers 321, 323 and 325 due to permeation of impurities such as external moisture and/or air. In some embodiments, the low refractive layer 330 may improve light efficiency of the display device 1. In more detail, the low refractive layer 330 may include a refractive index lower than that of each of the wavelength conversion layers 230 and 250 and the light-transmitting layer 270, thereby allowing the light passing through the wavelength conversion layers 230 and 250 and the light-transmitting layer 270 from the light emission areas LA1, LA2 and LA3 of the display substrate 10 to pass through the color filter layers 321, 323 and 325 without loss.

As described above, the display substrate 10 and the color conversion substrate 30 may face each other with the filler 70 therebetween. The filler 70 may be between the low refractive layer 330 and the bank pattern 290 by overlapping the non-light emission area NLA and the light-shielding area BA, and may be between the low refractive layer 330 and the first capping layer 283 by overlapping the light emission areas LA1, LA2 and LA3 and the light-transmissive areas TA1, TA2 and TA3.

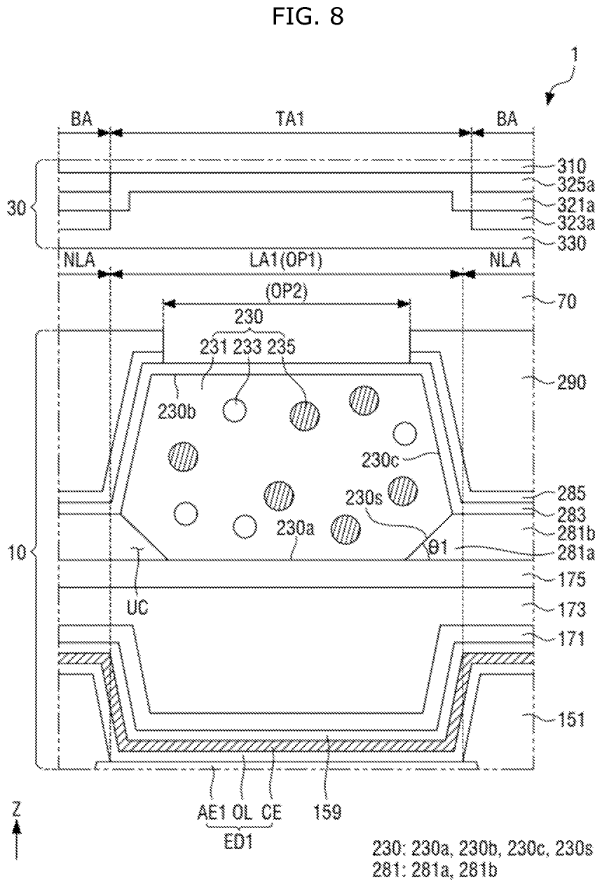

FIG. 8 is an enlarged cross-sectional view illustrating a portion of the first light emission area LA1 of FIG. 7.

Referring to FIG. 8, the first wavelength conversion layer 230 of the display device 1 may include a lower surface 230a, an upper surface 230b, a side 230c and an inclined surface 230s.

The lower surface 230a of the first wavelength conversion layer 230 may be one surface that is in contact (e.g., direct physical contact) with the third encapsulation layer 175, and the upper surface 230b of the first wavelength conversion layer 230 may be a surface facing the lower surface 230a. In some embodiments, the side 230c of the first wavelength conversion layer 230 may be one surface directed toward the bank pattern 290, and the inclined surface 230s of the first wavelength conversion layer 230 may be a surface connecting the lower surface 230a with the side 230c.

The wavelength conversion layers 230 and 250 and the light-transmitting layer 270 of the display device 1 included in the present disclosure may be formed by a photo process. In more detail, the wavelength conversion layers 230 and 250 and the light-transmitting layer 270 may be formed as shown through exposure and development processes after printing the materials of the wavelength conversion layers 230 and 250 and the light-transmitting layer 270 on the thin film encapsulation layer 170.

In some embodiments, the wavelength conversion layers 230 and 250 and the light-transmitting layer 270 may be exposed to an over-development caused by a manufacturing process. A portion of one surface of the wavelength conversion layers 230 and 250 and the light-transmitting layer 270, which is exposed to the over-development and directed toward the thin film encapsulation layer 170, may be lost.

The inclined surface 230s of the first wavelength conversion layer 230 may be formed by the over-development in the manufacturing process as described above. The inclined surface 230s of the first wavelength conversion layer 230 may be recessed inward from the side 230c of the first wavelength conversion layer 230. As shown in FIG. 8, an undercut UC may be formed below the inclined surface 230s of the first wavelength conversion layer 230. An inclined angle θ1 formed by the third encapsulation layer 175 and the inclined surface 230s of the first wavelength conversion layer 230 in a direction toward the non-light emission area NLA may be an acute angle.

In some embodiments, all structures, which overlap the light emission areas LA1, LA2 and LA3 and the light-transmissive areas TA1, TA2 and TA3 of the display device 1, may overlap the inclined surface 230s of the first wavelength conversion layer 230. For example, the pixel electrodes AE1, AE2 and AE3, the light emitting layer OL, the common electrode CE, the thin film encapsulation layer 170, the filler 70 and the color filter layer 320, which overlap the light emission areas LA1, LA2 and LA3 and the light-transmissive areas TA1, TA2 and TA3, may overlap the inclined surface 230s of the first wavelength conversion layer 230.

In some embodiments, the planarization layer 281 of the display device 1 may include a first portion 281a and a second portion 281b.

The first portion 281a of the planarization layer 281 may overlap the first light emission area LA1. The first portion 281a of the planarization layer 281 may be between the third encapsulation layer 175 and the inclined surface 230s of the first wavelength conversion layer 230. The first portion 281a of the planarization layer 281 may be in contact (e.g., direct physical contact) with the third encapsulation layer 175 that overlaps the first light emission area LA1, and may be in contact (e.g., direct physical contact) with the inclined surface 230s of the first wavelength conversion layer 230.

The first portion 281a of the planarization layer 281 may completely fill an undercut UC portion of the first wavelength conversion layer 230. The first portion 281a of the planarization layer 281 may planarize the undercut UC portion.

In some embodiments, when the undercut UC portion of the first wavelength conversion layer 230 is exposed without being covered by the planarization layer 281, a portion of the undercut UC portion may not be covered by the first capping layer 283. This may be caused because the undercut UC portion has a large curve and deep shape. A portion of the undercut UC that is not covered by the first capping layer 283 may be a path through which out-gassing of the bank pattern 290 is permeated. As a result, color efficiency of the first wavelength conversion layer 230 may be reduced.

The first portion 281a of the planarization layer 281 included in the present disclosure may fill the undercut UC portion of the first wavelength conversion layer 230, thereby assisting the first capping layer 283 to completely cover the first wavelength conversion layer 230 without an exposed portion.

The second portion 281b of the planarization layer 281 may overlap the non-light emission area NLA. The second portion 281b of the planarization layer 281 may be extended from the first portion 281a of the planarization layer 281. The second portion 281b of the planarization layer 281 may cover the third encapsulation layer 175, which overlaps the non-light emission area NLA, in contact (e.g., direct physical contact) with the third encapsulation layer 175.

As described above, the planarization layer 281 may include all organic materials that do not affect the lifespan of the wavelength conversion layers 230 and 250 and the light-transmitting layer 270. For example, the planarization layer 281 may include both a photo-curable organic material and a thermosetting organic material. A refractive index of the planarization layer 281, which includes an organic material, may have a value of 1.5 or less at a wavelength ranging from 380 nm to 680 nm.

In some embodiments, the planarization layer 281 may include first to third scatterers 233, 253 and 273 (e.g., first to third light scatterers 233, 253, and 273). A titanium oxide (TiO₂), a zirconium oxide (ZrO₂), an aluminum oxide (Al₂O₃), an indium oxide (In₂O₃), a zinc oxide (ZnO) and/or a tin oxide (SnO₂) may be examples of a material of the first to third scatterers 233, 253 and 273, and an acryl-based resin and/or a urethane-based resin may be examples of a material of the organic particle material.

In some embodiments, all structures, which overlap the light emission areas LA1, LA2 and LA3 and the light-transmissive areas TA1, TA2 and TA3 of the display device 1, may overlap the first portion 281a of the planarization layer 281. Therefore, a duplicative description thereof will not be repeated here.

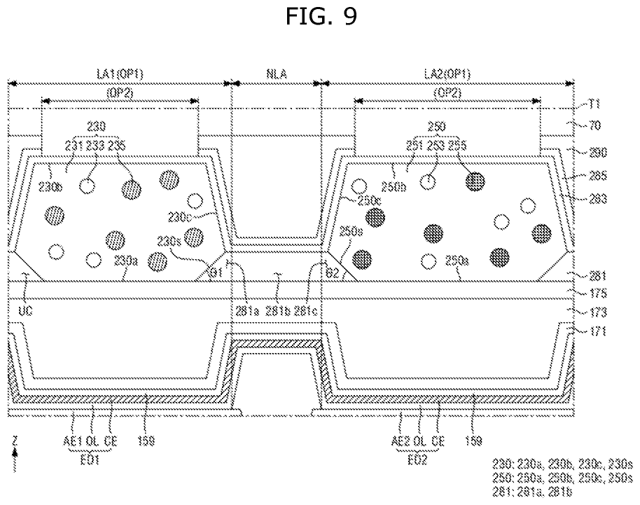

FIG. 9 is an enlarged cross-sectional view illustrating a portion ‘T1’ of FIG. 7.

Referring to FIG. 9, the second wavelength conversion layer 250 that overlaps the second light emission area LA2 may include a lower surface 250a, an upper surface 250b, a side 250c and an inclined surface 250s.

The lower surface 250a of the second wavelength conversion layer 250 may be one surface that is in contact (e.g., direct physical contact) with the third encapsulation layer 175, and the upper surface 250b of the second wavelength conversion layer 250 may be a surface facing the lower surface 250a. In some embodiments, the side 250c of the second wavelength conversion layer 250 may be one surface directed toward the bank pattern 290, and the inclined surface 250s of the second wavelength conversion layer 250 may be a surface connecting the lower surface 250a with the side 250c.

As described above, the inclined surface 250s of the second wavelength conversion layer 250 may be formed by the over-development in the manufacturing process of the display device 1. Therefore, an undercut UC may be formed below the inclined surface 250s of the second wavelength conversion layer 250. An inclined angle θ2 formed by the third encapsulation layer 175 and the inclined surface 250s of the second wavelength conversion layer 250 in a direction toward the non-light emission area NLA may be an acute angle.

In some embodiments, the planarization layer 281 included in the present embodiment may include a third portion 281c that overlaps the second light emission area LA2. The third portion 281c of the planarization layer 281 may overlap the second light emission area LA2. The third first portion 281a of the planarization layer 281 may be between the third encapsulation layer 175 and the inclined surface 250s of the second wavelength conversion layer 250. The third portion 281c of the planarization layer 281 may fill an undercut portion of the second wavelength conversion layer 250. The third portion 281c of the planarization layer 281 may planarize the undercut portion.

In some embodiments, the third portion 281c of the planarization layer 281 may be extended to the first portion 281a and the second portion 281b of the planarization layer 281. The second portion 281b of the planarization layer 281 may be between the first portion 281a and the third portion 281c. The first portion 281a, the second portion 281b and the third portion 281c of the planarization layer 281 included in the display device 1 may be integrally formed.

The first capping layer 283 may be on the first wavelength conversion layer 230, the planarization layer 281 and the second wavelength conversion layer 250. The first capping layer 283 may be in contact (e.g., direct physical contact) with the first wavelength conversion layer 230, the planarization layer 281 and the second wavelength conversion layer 250. In more detail, the first capping layer 283 may be in contact (e.g., direct physical contact) with the upper surface 230b and the side 230c of the first wavelength conversion layer 230 and extended to an upper surface of the planarization layer 281 as an extension line thereof. In some embodiments, the first capping layer 283 may be extended to the side 250c and the upper surface 250b of the second wavelength conversion layer 250.

In some embodiments, the first capping layer 283 may overlap the inclined surface 230s of the first wavelength conversion layer 230 and the inclined surface 250s of the second wavelength conversion layer 250, but the first capping layer 283 may not be in contact (e.g., may not be in direct physical contact) with the inclined surface 230s of the first wavelength conversion layer 230 and the inclined surface 250s of the second wavelength conversion layer 250.

The second capping layer 285 may be on an upper surface of the first capping layer 283. The second capping layer 285 may cover the first capping layer 283 and expose a portion of the first capping layer 283 by overlapping the second opening OP2. The second capping layer 285 may be between the first capping layer 283 and the bank pattern 290 by overlapping the non-light emission area NLA between the first light emission area LA1 and the second light emission area LA2.

The upper surface of the first capping layer 283 partially exposed by the second capping layer 285 and the upper surface of the bank pattern 290 may be covered by the filler 70 by overlapping the second opening OP2. The upper surface of the first capping layer 283 partially exposed by the second capping layer 285 and the upper surface of the bank pattern 290 may be in contact (e.g., direct physical contact) with the filler 70 by overlapping the second opening OP2.

Although the first wavelength conversion layer 230 and the second wavelength conversion layer 250 are illustrated for convenience of description, the light-transmitting layer 270 of the display device 1 may include the same structural feature as that of the first wavelength conversion layer 230 and the second wavelength conversion layer 250. In more detail, one surface of the light-transmitting layer 270, which is directed toward the third encapsulation layer 175, may be partially lost due to the over-development in the manufacturing process. As a result, one surface of the light-transmitting layer 270 may form an inclined surface having a shape similar to that of the first wavelength conversion layer 230 and the second wavelength conversion layer 250. Therefore, an undercut UC may be formed below the Inclined surface of the light-transmitting layer 270. An inclined angle formed by an inclined surface included in the light-transmitting layer 270 of the display device 1 and the third encapsulation layer 175 may be an acute angle. The undercut UC portion of the light-transmitting layer 270 may be covered by the planarization layer 281.

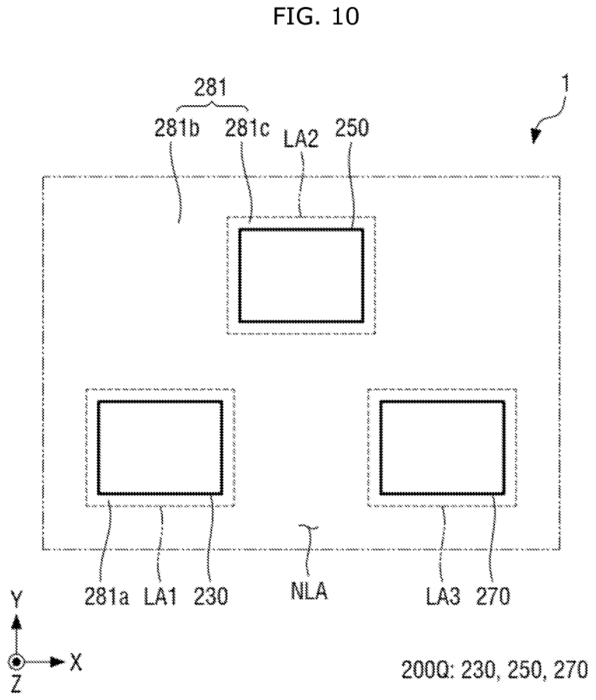

FIG. 10 is a schematic plan view illustrating the arrangement of the light control layer 2000 and the planarization layer 281 of FIG. 7.

Referring to FIG. 10, on a plane, the planarization layer 281 may surround the light control layer 2000 by overlapping the light emission areas LA1, LA2 and LA3. In more detail, the first portion 281a of the planarization layer 281 may surround the first wavelength conversion layer 230 by overlapping the first light emission area LA1. In some embodiments, the third portion 281c of the planarization layer 281 may surround the second wavelength conversion layer 250 by overlapping the second light emission area LA2.

As described above, on the cross-section, the light control layer 2000 of the display device 1 includes an inclined surface recessed toward an inner side thereof on one surface directed toward the thin film encapsulation layer 170 so that the first portion 281a and the third portion 281c of the planarization layer 281 may partially overlap the light control layer 2000 in the third direction (Z-axis direction). In this case, the first portion 281a and the third portion 281c of the planarization layer 281 on the plane may surround the light control layer 2000 in the light emission areas LA1, LA2 and LA3.

On the plane, the planarization layer 281 may surround the light emission areas LA1, LA2 and LA3 by overlapping the non-light emission area NLA. In more detail, the second portion 281b of the planarization layer 281 may surround the light emission areas LA1, LA2 and LA3 by overlapping the non-light emission area NLA. On the plane, the non-light emission area NLA of the display device 1 may be entirely covered by the second portion 281b of the planarization layer 281.

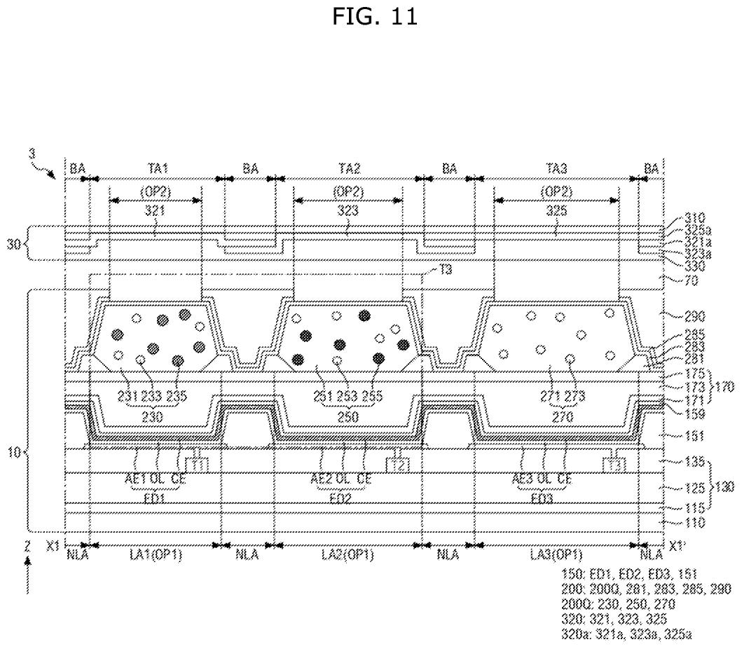

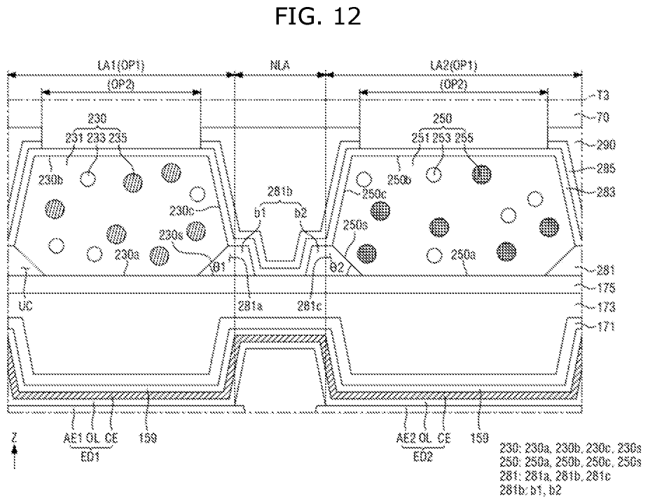

FIG. 11 is a cross-sectional view illustrating a display device according to another embodiment, which is taken along line X1-X1′ of FIG. 6. FIG. 12 is an enlarged cross-sectional view illustrating a portion ‘T3’ of FIG. 11.

The light control layer 2000 of the display device 3 may have the same shape as that of the light control layer 2000 of the display device 1. Hereinafter, a duplicative description will not be repeated here.

Referring to FIGS. 11-12, the planarization layer 281 of the display device 3 may include a first portion 281a that overlaps the first light emission area LA1, and a third portion 281c that overlaps the second light emission area LA2. As described above, the first portion 281a of the planarization layer 281 may be in contact (e.g., direct physical contact) with the inclined surface 230s of the first wavelength conversion layer 230, and may planarize an undercut UC portion of a lower end of the first wavelength conversion layer 230. In some embodiments, the third portion 281c of the planarization layer 281 may be in contact (direct physical contact) with the inclined surface 250s of the second wavelength conversion layer 250, and may planarize an undercut UC portion of a lower end of the second wavelength conversion layer 250. The inclined angle θ1 formed by the third encapsulation layer 175 and the inclined surface 230s of the first wavelength conversion layer 230 and the inclined angle θ2 formed by the third encapsulation layer 175 and the inclined surface 250s of the second wavelength conversion layer 250 may be acute angles.

This embodiment is different from the other embodiments in that the second portion 281b of the planarization layer 281 included in the display device 3 includes a first sub-portion b1 and a second sub-portion b2. The first sub-portion b1 of the planarization layer 281 may be extended from the first portion 281a of the planarization layer 281 that overlaps the first light emission area LA1, and the second sub-portion b2 of the planarization layer 281 may be extended from the third portion 281c of the planarization layer 281 that overlaps the second light emission area LA2. The first sub-portion b1 and the second sub-portion b2 of the planarization layer 281 may be spaced apart from each other while partially exposing the third encapsulation layer 175 by overlapping the non-light emission area NLA.

The first capping layer 283 of the display device 3 may be in contact (e.g., direct physical contact) with the first sub-portion b1 and the second sub-portion b2 of the planarization layer 281 by overlapping the non-light emission area NLA. The first capping layer 283 of the display device 3 may cover the first sub-portion b1 and the second sub-portion b2 of the planarization layer 281 by overlapping the non-light emission area NLA. In a portion where the first sub-portion b1 and the second sub-portion b2 of the planarization layer 281 are spaced apart from each other, the first capping layer 283 may be partially in contact (e.g., direct physical contact) with the third encapsulation layer 175.

The second capping layer 285 of the display device 3 may cover the first capping layer 283 by overlapping the non-light emission area NLA. Therefore, the first capping layer 283 may be between the third encapsulation layer 175 and the second capping layer 285 in the portion where the first sub-portion b1 and the second sub-portion b2 of the planarization layer 281 are spaced apart from each other.

The bank pattern 290 of the display device 3 may be on the second capping layer 285 in the portion where the first sub-portion b1 and the second sub-portion b2 of the planarization layer 281 are spaced apart from each other. The bank pattern 290 may partially fill the spaced portion of the first sub-portion b1 and the second sub-portion b2. Therefore, the bank pattern 290 may have a shape protruded toward the display substrate 10 by overlapping the non-light emission area NLA. A portion of the bank pattern 290, which is protruded, may fill the spaced portion of the first sub-portion b1 and the second sub-portion b2. A duplicative description thereof will not be repeated here.

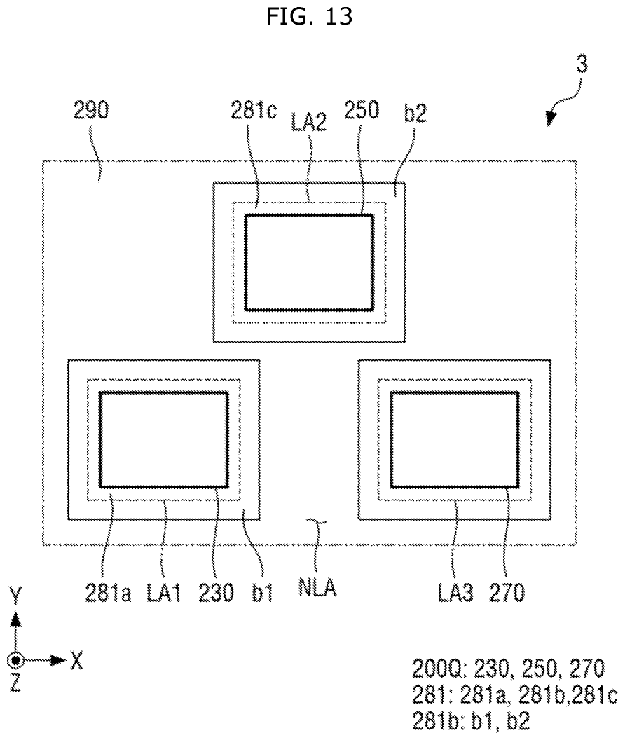

FIG. 13 is a schematic plan view illustrating the arrangement of the light control layer 2000 and the planarization layer 281 of FIG. 11.

Referring to FIG. 13, on the plane, the planarization layer 281 of the display device 3 may surround the light control layer 2000 by overlapping the light emission areas LA1, LA2 and LA3. In more detail, on the plane, the first portion 281a of the planarization layer 281 may surround the first wavelength conversion layer 230 by overlapping the first light emission area LA1. In some embodiments, the third portion 281c of the planarization layer 281 may surround the second wavelength conversion layer 250 by overlapping the second light emission area LA2. A duplicative description thereof will not be repeated here.

On the plane, the planarization layer 281 of the display device 3 may surround the light emission areas LA1, LA2 and LA3 by overlapping the non-light emission area NLA. In some embodiments, the planarization layer 281 of the display device 3, which overlaps the non-light emission area NLA, may be surrounded by the bank pattern 290. In more detail, by overlapping the non-light emission area NLA, the first sub-portion b1 of the planarization layer 281 may surround the first light emission area LA1, and the second sub-portion b2 of the planarization layer 281 may surround the second light emission area LA2. The first sub-portion b1 and the second sub-portion b2 of the second portion 281b may be surrounded by the bank pattern 290 by overlapping the non-light emission area NLA.

Although the first wavelength conversion layer 230 and the second wavelength conversion layer 250 of the display device 3 are illustrated for convenience of description, the light-transmitting layer 270, which overlaps the third light emission area LA3 of the display device 3, may also include the same structure as that of the wavelength conversion layers 230 and 250.

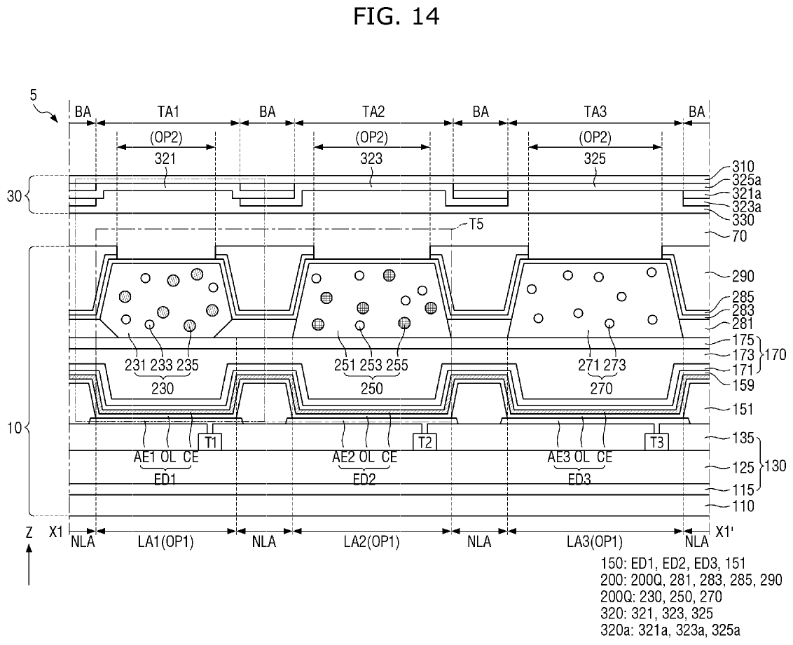

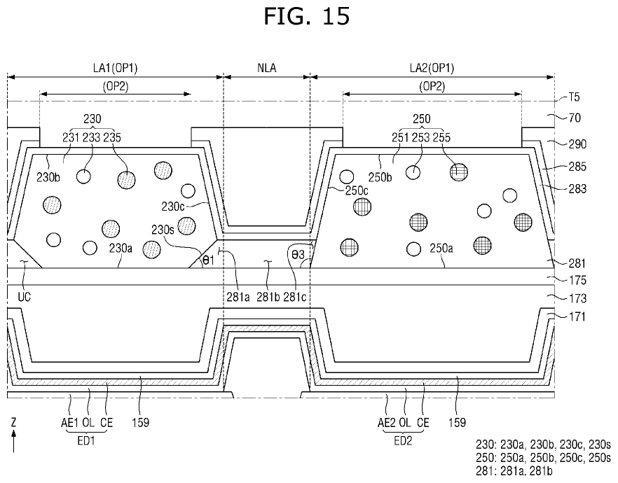

FIG. 14 is a cross-sectional view illustrating a display device 5 according to another embodiment, which is taken along the line X1-X1′ of FIG. 6. FIG. 15 is an enlarged cross-sectional view illustrating a portion ‘T5’ of FIG. 14.

Referring to FIGS. 14-15, the first wavelength conversion layer 230 of the display device 5 may include a lower surface 230a, an upper surface 230b, a side 230c and an inclined surface 230s. The lower surface 230a of the first wavelength conversion layer 230 may be one surface that is in contact (e.g., direct physical contact) with the third encapsulation layer 175, and the upper surface 230b of the first wavelength conversion layer 230 may be a surface facing the lower surface 230a. In some embodiments, the side 230c of the first wavelength conversion layer 230 may be one surface directed toward the bank pattern 290, and the inclined surface 230s of the first wavelength conversion layer 230 may be a surface connecting the lower surface 230a with the side 230c. An inclination angle θ1 formed by the inclined surface 230s of the first wavelength conversion layer 230 and the third encapsulation layer 175 may be an acute angle.

In some embodiments, the second wavelength conversion layer 250 of the display device 5 may include a lower surface 250a, an upper surface 250b and a side 250c. The lower surface 250a of the second wavelength conversion layer 250 may be one surface that is in contact (e.g., direct physical contact) with the third encapsulation layer 175, and the upper surface 250b of the second wavelength conversion layer 250 may be a surface facing the lower surface 250a. In some embodiments, the side 250c of the second wavelength conversion layer 250 may be one surface directed toward the bank pattern 290. The side 250c of the second wavelength conversion layer 250 may be an inclined surface. Therefore, the side 250c of the second wavelength conversion layer 250 and the third encapsulation layer 175 may form an inclined angle. An inclined angle θ3 formed by the side 250c of the second wavelength conversion layer 250 and the third encapsulation layer 175 in a direction toward the non-light emission area NLA may be an obtuse angle. This embodiment is different from the other embodiments in that the inclined surface of the second wavelength conversion layer 250 included in the display device 5 is formed at an obtuse angle with the third encapsulation layer 175.

The planarization layer 281 of the display device 5 may include a first portion 281a that overlaps the first light emission area LA1, and a second portion 281b that overlaps the non-light emission area NLA. The second portion 281b that overlaps the non-light emission area NLA may be extended from the first portion 281a of the planarization layer 281 that overlaps the first light emission area LA1.

In some embodiments, the planarization layer 281 of the display device 5 may include a third portion 281c that overlaps the second light emission area LA2, but the present disclosure is not limited thereto. The planarization layer 281 of the display device 5 may not overlap the second light emission area LA2 depending on a shape in which the second wavelength conversion layer 250 overlaps the second light emission area LA2. In some embodiments, the planarization layer 281 of the display device 5 may overlap the first light emission area LA1, the non-light emission area NLA and the second light emission area LA2, or in some embodiments, the planarization layer 281 of the display device 5 may overlap only the first light emission area LA1 and the non-light emission area NLA.

As shown in FIG. 14, the light-transmitting layer 270 of the display device 5 may include the same structure and features as those of the second wavelength conversion layer 250 of the display device 5. In some embodiments, the light-transmitting layer 270 of the display device 5 may include a side directed toward the bank pattern 290, and an inclined angle formed by the side of the light-transmitting layer 270 and the third encapsulating layer 175 in a direction toward the non-light emission area NLA may be an obtuse angle.

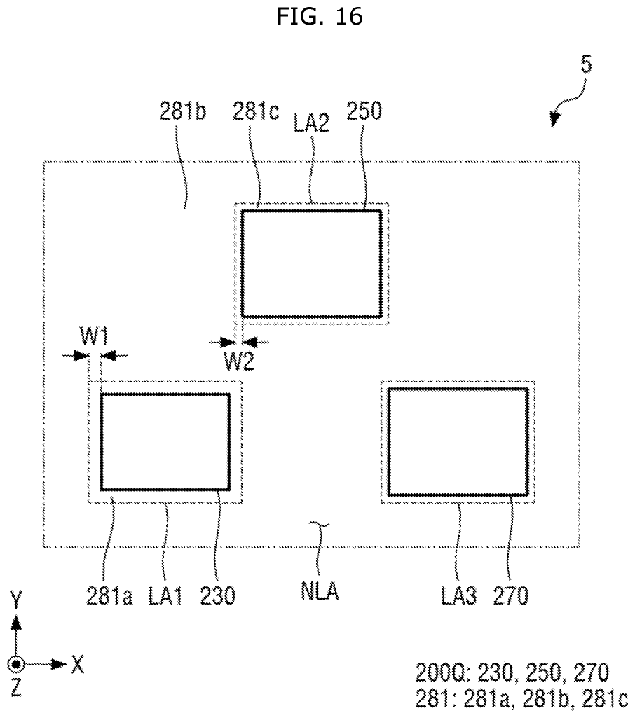

FIG. 16 is a schematic plan view illustrating the arrangement of the light control layer 2000 and the planarization layer 281 of FIG. 14.

Referring to FIG. 16, on the plane, the planarization layer 281 of the display device 5 may surround the light control layer 2000 by overlapping the light emission areas LA1, LA2 and LA3. In more detail, the first portion 281a of the planarization layer 281 may surround the first wavelength conversion layer 230 by overlapping the first light emission area LA1. The first portion 281a of the planarization layer 281 and the first wavelength conversion layer 230 may overlap each other in the third direction (Z-axis direction) in the first light emission area LA1. In some embodiments, the third portion 281c of the planarization layer 281 may surround the second wavelength conversion layer 250 by overlapping the second light emission area LA2.

A width W1 of the first portion 281a of the planarization layer 281 surrounding the first wavelength conversion layer 230 in the first light emission area LA1 may be greater than a width W2 of the planarization layer 281 surrounding the second wavelength conversion layer 250 in the second light emission area LA2.

On the plane, the planarization layer 281 of the display device 5 may surround the light emission areas LA1, LA2 and LA3 by overlapping the non-light emission area NLA. In more detail, the second portion 281b of the planarization layer 281 may surround the light emission areas LA1, LA2 and LA3 by overlapping the non-light emission area NLA. On the plane, the second portion 281b of the planarization layer 281 may entirely cover the non-light emission area NLA.

In concluding the detailed description, those skilled in the art will appreciate that many variations and modifications can be made to the described embodiments without substantially departing from the spirit and scope of the present disclosure. Therefore, the disclosed embodiments of the present disclosure are used in a generic and descriptive sense and not for purposes of limitation.

What is claimed is:

1. A display device comprising:
a first substrate comprising a light emission area and a non-light emission area;
a first pixel electrode on the light emission area of the first substrate;
a pixel defining layer on the non-light emission area of the first substrate, defining a first opening;
a thin film encapsulation layer on the first pixel electrode and the pixel defining layer;
a first light control layer overlapping the light emission area, on the thin film encapsulation layer;
a planarization layer on the thin film encapsulation layer; and
a bank pattern overlapping the non-light emission area, on the planarization layer and defining a second opening,
wherein the first light control layer comprises a first surface directed toward the first pixel electrode, a first side directed toward the bank pattern, and a first inclined surface connecting the first surface with the first side, and
the planarization layer is in contact with the first inclined surface.

2. The display device of claim 1, wherein the first light control layer and the planarization layer are on the thin film encapsulation layer in contact with the thin film encapsulation layer, and
an inclined angle formed by the thin film encapsulation layer and the first inclined surface in a direction toward the non-light emission area is an acute angle.

3. The display device of claim 2, wherein the planarization layer is between the thin film encapsulation layer and the first inclined surface by overlapping the light emission area.

4. The display device of claim 3, wherein the planarization layer completely fills a space between the thin film encapsulation layer and the first inclined surface by overlapping the light emission area.

5. The display device of claim 4, wherein the first light control layer comprises one selected from a quantum dot material and an organic material.

6. The display device of claim 4, wherein the planarization layer comprises a metal scatterer.

7. The display device of claim 1, further comprising second light control layers spaced apart from each other with the planarization layer therebetween,
wherein the second light control layer comprises a second inclined surface that is in contact with the planarization layer.

8. The display device of claim 7, wherein the planarization layer further comprises a first portion that is in contact with the first inclined surface, a second portion that overlaps the non-light emission area, and a third portion that is in contact with the second inclined surface, and
the second portion is between the first portion and the third portion.

9. The display device of claim 8, wherein the first portion and the third portion are extended by the second portion, and
the first portion, the second portion and the third portion are integrally formed.

10. The display device of claim 8, wherein the second portion further comprises a first sub-portion extended from the first portion and a second sub-portion extended from the third portion, and
the first sub-portion and the second sub-portion are spaced apart from each other with the bank pattern therebetween.

11. The display device of claim 7, wherein an inclined angle formed by the thin film encapsulation layer and the second inclined surface in a direction toward the non-light emission area is an acute angle.

12. The display device of claim 7, wherein an inclined angle formed by the thin film encapsulation layer and the second inclined surface in a direction toward the non-light emission area is either a right angle or an obtuse angle.

13. The display device of claim 7, further comprising a first capping layer completely covering the first light control layer, the planarization layer and the second light control layer,
wherein the first capping layer is in contact with the first light control layer, the planarization layer and the second light control layer.

14. The display device of claim 13, wherein the planarization layer is completely surrounded by the first light control layer, the first capping layer, the second light control layer and the thin film encapsulation layer.

15. The display device of claim 13, wherein the planarization layer is completely surrounded by the first light control layer, the first capping layer and the thin film encapsulation layer.

16. The display device of claim 1, further comprising:
a second substrate comprising a light-transmissive area and a light-shielding area; and
a color filter layer on the light-transmissive area of the second substrate and toward the first substrate,
wherein the second substrate faces the first substrate with a filler therebetween, and
the color filter layer overlaps the first inclined surface of the first light control layer.

17. The display device of claim 1, wherein a width of the first opening in a parallel direction of the first substrate is greater than a width of the second opening.

18. A display device comprising:
a substrate comprising a first light emission area, a second light emission area and a non-light emission area between the first light emission area and the second light emission area;
a pixel electrode on the first light emission area of the substrate;
a pixel defining layer on the non-light emission area of the substrate;
a first light control layer on the pixel electrode;
a planarization layer on the pixel electrode and the pixel defining layer; and
a bank pattern overlapping the non-light emission area, on the planarization layer,
wherein the planarization layer comprises a first portion that overlaps the first light emission area, and a second portion that overlaps the first light emission area, and
on a plane, the first portion surrounds the first light control layer and the second portion surrounds the first light emission area.

19. The display device of claim 18, further comprising a second light control layer that overlaps the second light emission area,
wherein the planarization layer further comprises a third portion that overlaps the second light emission area,
the third portion surrounds the second light control layer on a plane, and
a width of the first portion is greater than that of the third portion on the plane.

20. The display device of claim 18, wherein the second portion is surrounded by the bank pattern by overlapping the non-light emission area on a plane.
